(19) United States
(12) Patent Application Publication
(10) Pub. No.: US 2016/0107376 A1
(43) Pub. Date: Apr. 21, 2016

(54) METAL-RESIN COMPOSITE BODY, WIRING MATERIAL, AND METHOD FOR PRODUCING METAL-RESIN COMPOSITE BODY

(71) Applicant: SUMITOMO ELECTRIC INDUSTRIES, LTD., Osaka (JP)

(72) Inventors: Shingo NAKAJIMA, Osaka-shi (JP); Jun SUGAWARA, Osaka-shi (JP); Shingo KAIMORI, Osaka-shi (JP); Hideo ARAMAKI, Osaka-shi (JP); Makoto NAKABAYASHI, Osaka-shi (JP); Katsuya YAMADA, Osaka (JP)

(21) Appl. No.: 14/893,973

(22) PCT Filed: May 27, 2014
(86) PCT No.: PCT/JP2014/063917

§ 371 Date: Nov. 25, 2015

(30) Foreign Application Priority Data
May 31, 2013 (JP) 2013-116497

(51) Int. Cl. B29C 65/00; H05K 1/03; H05K 3/00; B29C 65/48

(52) U.S. Cl. CPC B29C 66/742; B29C 65/4865; B29C 66/712; H05K 1/0393; H05K 1/0353; H05K 3/0055; B29K 2627/18

(57) ABSTRACT

An object is to provide a metal-resin composite body (1) having good high-frequency signal transmission characteristics and good adhesiveness between a synthetic resin portion (2) and a base portion (3). The present invention provides a metal-resin composite body including a base portion composed of a metal, and a synthetic resin portion that is bonded to at least a part of an outer surface of the base portion and that contains a fluororesin as a main component, in which a silane coupling agent which has a functional group containing a N atom or a S atom is present in the vicinity of an interface between the base portion and the synthetic resin portion. The silane coupling agent is preferably an aminoalkoxysilane, an ureidoalkoxysilane, a mercaptoalkoxysilane, a sulfide alkoxysilane, or a derivative thereof. The silane coupling agent is preferably an aminoalkoxysilane to which a modifying group is introduced. The modifying group is preferably a phenyl group. The fluororesin is preferably FEP, PFA, PTFE, or TFE/PDD.

### TECHNICAL FIELD

The present invention relates to a metal-resin composite body, a wiring material, and a method for producing a metal-resin composite body.

### BACKGROUND ART

Personal digital assistants such as mobile phones require a small thickness, a light weight, ease of portability, etc. On the other hand, the volume in which electronic components can be mounted is limited in personal digital assistants. Therefore, a flexible wiring board such as a flexible printed circuit board (FPC), a tape electrical wire, or a micro coaxial cable, which enables effective use of the volume in which electronic components can be mounted, may be used for mounting electronic components. Such a flexible wiring board is produced by forming a conductor layer on a surface of a flexible base. Hard (rigid) wiring boards are also used.

Recent personal digital assistants can perform high-speed large-capacity communication. In such high-speed large-capacity communication, a high-frequency signal flows through an electronic circuit on a base. Therefore, wiring boards are required to have good transmission characteristics, specifically, to have a low transmission delay and a low transmission loss. In order to obtain such transmission characteristics, it is necessary to use a base material having a small relative dielectric constant (Er) and a small dielectric loss tangent (tan δ).

Fluororesins such as polytetrafluoroethylene (PTFE) are known examples of such base materials having a small relative dielectric constant (Er) and a small dielectric loss tangent (tan δ) (refer to, for example, Japanese Unexamined Patent Application Publication No. 2001-7466 and Japanese Patent No. 4296250). However, since fluororesins such as PTFE have a very low surface energy and are non-adhesive, adhesiveness between a base and a conductor layer may not be sufficiently ensured.

An example of means for enhancing the adhesiveness is a method in which a primer layer composed of a polyimide or a mixture of a polyimide and polyethersulfone is formed between a metal base and a covering layer composed of a fluoropolymer (for example, Japanese Unexamined Patent Application Publication No. 2000-326441). As another means, a method in which a surface of a metal base is roughened by etching or the like has been proposed (for example, Japanese Unexamined Patent Application Publication No. 3-207473).

### CITATION LIST

### Patent Literature

PTL 1: Japanese Unexamined Patent Application Publication No. 2001-7466

PTL 2: Japanese Patent No. 4296250

PTL 3: Japanese Unexamined Patent Application Publication No. 2000-326441

PTL 4: Japanese Unexamined Patent Application Publication No. 3-207473

### SUMMARY OF INVENTION

### Technical Problem

However, in the method in which a primer layer is formed, the relative dielectric constant of the covering layer may be increased in some types of resin material that forms the primer layer. On the other hand, in the method in which a surface of a metal base is roughened, a transmission delay is easily generated by a skin effect, and a transmission loss may be increased by an increase in resistance attenuation or leakage attenuation.

The present invention has been made in view of the above circumstances. An object of the present invention is to provide a metal-resin composite body having good high-frequency signal transmission characteristics and good adhesiveness between a synthetic resin portion and a base portion.

### Solution to Problem

An aspect of the present invention provides

a metal-resin composite body including a base portion composed of a metal, and a synthetic resin portion that is bonded to at least a part of an outer surface of the base portion and that contains a fluororesin as a main component,

in which a silane coupling agent which has a functional group containing a N atom or a S atom is present in the vicinity of an interface between the base portion and the synthetic resin portion.

Another aspect of the present invention provides

a wiring material including the metal-resin composite body.

Still another aspect of the present invention provides

a method for producing a metal-resin composite body, the method including the steps of:

applying a composition containing a silane coupling agent which has a functional group containing a N atom or a S atom onto at least a part of an outer surface of a base portion composed of a metal,

drying the composition, and

bonding a synthetic resin portion containing a fluororesin as a main component to at least a composition-applied surface in the outer surface of the base portion.

### Advantageous Effects of Invention

According to the present invention, a metal-resin composite body having good high-frequency signal transmission characteristics and good adhesiveness between a synthetic resin portion and a base portion is provided. Accordingly, the metal-resin composite body of the present invention can be suitably used in a wiring material such as a tape electrical wire or an FPC. According to the present invention, a method for producing a metal-resin composite body having good high-frequency signal transmission characteristics and good adhesiveness is further provided.

### BRIEF DESCRIPTION OF DRAWINGS

FIG. 1 is a schematic cross-sectional view illustrating a metal-resin composite body according to an embodiment of the present invention.

FIG. 2 is a schematic cross-sectional view illustrating a metal-resin composite body according to another embodiment of the present invention.

FIG. 3 is a schematic cross-sectional view illustrating a metal-resin composite body according to another embodiment of the present invention.

FIG. 4 is a schematic plan view illustrating a tape electrical wire which is an embodiment of a wiring material of the present invention.

FIG. 5 is a schematic cross-sectional view taken along line X1-X1 in FIG. 4.

FIG. 6 is a schematic plan view illustrating a flexible printed circuit board which is another embodiment of a wiring material of the present invention.

FIG. 7 is a schematic cross-sectional view taken along line X2-X2 in FIG. 6.

FIG. 8 is a schematic cross-sectional view of a fluororesin base which is another embodiment of the present invention.

### DESCRIPTION OF EMBODIMENTS

### Description of Embodiments of Present Invention

An aspect of the present invention that has been made in order to solve the above problems provides

a metal-resin composite body including a base portion composed of a metal, and a synthetic resin portion that is bonded to at least a part of an outer surface of the base portion and that contains a fluororesin as a main component,

in which a silane coupling agent which has a functional group containing a N atom or a S atom is present in the vicinity of an interface between the base portion and the synthetic resin portion.

In the metal-resin composite body, since a silane coupling agent which has a functional group containing a N atom or a S atom is present in the vicinity of an interface between a base portion and a synthetic resin portion, adhesiveness between the synthetic resin portion and the base portion is enhanced. Although the reason for this is not clear, it is believed that while a hydrolyzable group of the coupling agent is fixed to the base portion, the functional group of the silane coupling agent, the functional group containing a N atom or a S atom, such as an amino group or a sulfide group, is chemically bonded to a C═O or COOH portion generated when a fluororesin, which is a main component of the synthetic resin portion, is converted into radicals, thereby improving the adhesiveness.

In addition, since the adhesiveness in the metal-resin composite body is enhanced by the presence of the silane coupling agent in the vicinity of the interface between the synthetic resin portion and the base portion, it is possible to suppress disadvantages of the existing methods such as the method in which a primer layer is formed between a metal base and a covering layer composed of a fluororesin polymer, and the method in which a surface of a metal base is roughened. Specifically, an increase in the relative dielectric constant of the synthetic resin portion can be suppressed. In addition, when the metal-resin composite body is used in a wiring material, an increase in the transmission loss due to an increase in resistance attenuation or leakage attenuation can be suppressed. Therefore, the metal-resin composite body can provide a wiring material having good high-frequency signal transmission characteristics.

The silane coupling agent is preferably an aminoalkoxysilane, an ureidoalkoxysilane, a mercaptoalkoxysilane, a sulfide alkoxysilane, or a derivative thereof. When such a silane coupling agent is present in the vicinity of the interface between the synthetic resin portion and the base portion, the adhesiveness between the synthetic resin portion and the base portion can be effectively enhanced.

The silane coupling agent is preferably an aminoalkoxysilane to which a modifying group is introduced. When such an aminoalkoxysilane is present in the vicinity of the interface between the synthetic resin portion and the base portion, the adhesiveness between the synthetic resin portion and the base portion can be more effectively enhanced.

The modifying group is preferably a phenyl group. When the silane coupling agent has a phenyl group introduced thereto, the adhesiveness between the synthetic resin portion and the base portion can be more effectively enhanced.

The fluororesin which is the main component of the synthetic resin portion is preferably a tetrafluoroethylene/hexafluoropropylene copolymer (FEP), a tetrafluoroethylene/perfluoroalkyl vinyl ether copolymer (PFA), polytetrafluoroethylene (PTFE), or a tetrafluoroethylene/perfluorodioxole copolymer (TFE/PDD). It is believed that these fluororesins easily generate fluorine radicals as a result of heating, electron beam irradiation, or the like. Therefore, the metal-resin composite body including a synthetic resin portion that contains any of the exemplified fluororesins as the main component has excellent adhesiveness between the synthetic resin portion and the base portion.

The base portion preferably includes a rustproofing layer on a surface bonded to the synthetic resin portion side. By providing a rustproofing layer on the base portion, oxidation of the bonding surface of the base portion can be suppressed. As a result, a decrease in the adhesive force due to oxidation of the base portion can be suppressed.

The rustproofing layer preferably contains a cobalt oxide. By incorporating a cobalt oxide in the rustproofing layer, a decrease in adhesiveness of the base portion can be more effectively suppressed.

A peeling strength between the base portion and the synthetic resin portion is preferably 3 N/cm or more. When the peeling strength of the base portion is equal to or more than the above value, the metal-resin composite body can be suitably used as a wiring material such as a tape electrical wire or a flexible printed circuit board.

Preferably, each of the base portion and the synthetic resin portion is formed of a film, has flexibility, and has a thickness of 1 to 5,000 μm, and preferably 5 to 50 μm. When the base portion and the synthetic resin portion each have a thickness of 1 to 5,000 the metal-resin composite body can be suitably used in a wiring material such as a tape electrical wire or a flexible printed circuit board.

Another aspect of the present invention that has been made in order to solve the above problems provides

a wiring material including the metal-resin composite body.

Since the wiring material includes the metal-resin composite body, the wiring material has good high-frequency signal transmission characteristics and good adhesiveness between the synthetic resin portion and the base portion. Accordingly, the wiring material can be suitably used in, for example, a personal digital assistant to which a high-frequency signal is transmitted.

Another aspect of the present invention that has been made in order to solve the above problems provides

a method for producing a metal-resin composite body, the method including the steps of:

applying a composition containing a silane coupling agent which has a functional group containing a N atom or a S atom onto at least a part of an outer surface of a base portion composed of a metal,

drying the composition, and

bonding a synthetic resin portion containing a fluororesin as a main component to at least a composition-applied surface in the outer surface of the base portion.

According to the production method, it is possible to provide a metal-resin composite body in which the silane coupling agent is present in the vicinity of an interface between the synthetic resin portion and the base portion. Therefore, the metal-resin composite body provided by the production method has good high-frequency signal transmission characteristics and good adhesiveness between the synthetic resin portion and the base portion.

Herein, the term “fluororesin” refers to a resin in which at least one hydrogen atom bonded to a carbon atom constituting a repeating unit of a polymer chain is substituted with a fluorine atom or an organic group having a fluorine atom. The term “main component” refers to a component having a highest content, for example, a component having a content of 50% by mass or more. The term “peeling strength” refers to a peel strength measured in accordance with JIS K 6854-2:1999 “Adhesives-Determination of peel strength of bonded assemblies, Part 2: 180 degree peel”. This peel strength can be measured using, for example, an “Autograph AG-IS” tensile tester (manufactured by Shimadzu Corporation).

Next, another embodiment of the present invention will be described. A metal-resin composite body is formed by combining a metal base portion that contains a silane coupling agent with a synthetic resin portion that contains a fluororesin as a main component, and the base portion is then removed by etching and washing is performed. In this case, even after a surface resistance of the synthetic resin portion is confirmed to be 10¹³ or more, a bond between the fluororesin of the synthetic resin portion and silane remains. Therefore, a surface (modified layer) of the synthetic resin portion which contains the fluororesin as a main component and from which the base portion has been removed has a siloxane-bond structure, contains a functional group other than a siloxane group, and has a contact angle with pure water of 90° or less. Accordingly, there is provided a fluororesin base that includes a fluororesin layer and a modified layer formed on at least a part of a surface of the fluororesin layer, in which the modified layer has a siloxane-bond structure, contains a functional group other than a siloxane group, and has hydrophilicity represented by a contact angle with pure water of 90° or less.

Since the modified layer containing a fluororesin and a silane coupling agent has hydrophilicity represented by a contact angle with pure water of 90° or less, the fluororesin base is rich in reactivity. Herein, the term “rich in reactivity” covers a case where a physical action such as an adhesive property is large. Therefore, the fluororesin base is surface-active. In addition, since the modified layer has a siloxane-bond structure, the modified layer is stable with time.

Specifically, in the fluororesin base having the above structure, the surface-modified state (surface-active state) is more stable than those of existing fluororesins. Note that the term “surface-modified state” refers to a state that is surface-active as compared with an original fluororesin. More specifically, the “surface-modified state” means that at least one of the following is satisfied. The contact angle between a surface and a polar solvent is smaller, the reactivity with a chemical substance is higher, and the adhesive property (peeling strength) with a resin is higher than those of the original fluororesin base.

In the part where the modified layer of the fluororesin base is formed, a peeling strength of a polyimide sheet bonded with an epoxy resin adhesive is preferably 1.0 N/cm or more. With this structure, the polyimide sheet is not easily detached from the fluororesin base. Note that the peeling strength is a value measured by the method according to JIS K 6854-2:1999 “Adhesives-Determination of peel strength of bonded assemblies, Part 2: 180 degree peel”.

The modified layer of the fluororesin base preferably has the following structure. Specifically, the modified layer preferably has etching resistance to an etching treatment including immersion using an etchant containing iron chloride, having a specific gravity of 1.31 g/cm³ or more and 1.33 g/cm³ or less, and a free hydrochloride concentration of 0.1 mol/L or more and 0.2 mol/L or less at 45° C. or lower for two minutes or less.

With this structure, even when a metal layer is formed on the fluororesin base and an etching treatment is performed, the surface-modified state (surface activity) of the fluororesin base can be maintained. Therefore, in the case where various treatments are performed on the fluororesin base after the etching treatment, the state after the treatments can be made satisfactory.

In the fluororesin base, the modified layer preferably has a thickness of 400 nm or less on average. With this structure, it is possible to suppress a decrease in high-frequency characteristics due to the thickness of the modified layer when the fluororesin base is used as a wiring board, compared with the case where the thickness of the modified layer is more than 400 nm on average.

The fluororesin base of the present embodiment can be used as a printed circuit board. In the printed circuit board, a covering material that covers at least a part of the fluororesin base is preferably provided on the modified layer. According to this structure, the peeling strength of the covering material can be made higher than that in the case where the covering material adheres directly to the fluororesin. Examples of the covering material include a covering resin and a covering member.

Furthermore, the fluororesin base having the above structure may also be used as the covering material (for example, a coverlay film). That is, a fluororesin, which is a low dielectric material, is used as both the fluororesin base and the covering material. With this structure, a high-frequency circuit module having a low loss of signal transmission can be obtained. The circuit module includes, for example, a printed circuit board formed of a fluororesin base, an electronic component mounted on the circuit board, a conductive layer (wiring) connected to the electronic component, and a covering material such as a solder resist or a coverlay film.

Examples of the fluororesin constituting the fluororesin layer of the fluororesin base include, in addition to the fluororesins mentioned above, polyvinylidene fluoride, polychlorotrifluoroethylene, chlorotrifluoroethylene/ethylene copolymers, polyvinyl fluoride, fluororesins (THV) obtained from three monomers of tetrafluoroethylene, hexafluoropropylene, and vinylidene fluoride, and fluoroelastomers. Furthermore, mixtures and copolymers that contain these compounds are also used. In order to improve bending strength, heat resistance, and heat dissipation properties, a fluororesin containing a filler may be used as the material constituting the fluororesin layer in accordance with the use thereof. Furthermore, in order to improve bending strength of the fluororesin layer or to make linear expansion close to that of a conductive layer, an intermediate layer including a fiber sheet (for example, a glass cloth, an liquid crystal polymer (LCP) cloth, an aramid cloth, an alumina cloth, or a polyimide (PI) film) may be provided on the fluororesin layer. The fluororesin layer may have a hollow structure.

The intermediate layer is not particularly limited as long as the intermediate layer has a coefficient of linear expansion smaller than that of the fluororesin layer. However, the intermediate layer preferably has insulating properties, heat resistance in which the layer does not melt or flow at a melting point of the fluororesin, tensile strength equal to or higher than that of the fluororesin, corrosiveness to the fluororesin, and a coefficient of linear expansion described below. The intermediate layer may be constituted by, for example, a glass cloth obtained by forming glass in the form of a cloth; a fluororesin-containing glass cloth obtained by impregnating such a glass cloth with a fluororesin; a resin cloth obtained by forming heat-resistant fibers composed of a metal, a ceramic, alumina, PTFE, polyether ether ketone (PEEK), PI, aramid, or the like in the form of a cloth or a nonwoven fabric; or a heat-resistant film containing, as a main component, PTFE, LCP (Type I), PI, polyamide-imide (PAI), polybenzimidazole (PBI), PEEK, PTFE, PFA, a thermosetting resin, a cross-linked resin, or the like. These heat-resistant resins and heat-resistant films have a melting point (or a heat deflection temperature) equal to or higher than a temperature in a step of bonding a fluororesin and a conductor.

The weave of the cloth is preferably a plain weave in order to reduce the thickness of the intermediate. However, a twill weave, a satin weave, or the like is preferable in use for bending. Besides, other publicly known weaves may be used.

The density of glass fibers of the glass cloth is preferably 1 g/m³ or more and 5 g/m³ or more, and more preferably 2 g/m³ or more and 3 g/m³ or more. The tensile strength of the glass fibers is preferably 1 GPa or more and 10 GPa or less, and more preferably 2 GPa or more and 5 GPa or less. The modulus of elasticity in tension of the glass fibers is preferably 10 GPa or more and 200 GPa or less, and more preferably 50 GPa or more and 100 GPa or less. The maximum elongation percentage of the glass fibers is preferably 1% or more and 20% or less, and more preferably 3% or more and 10% or less. The softening point of the fibers is preferably 700° C. or higher and 1,200° C. or lower, and more preferably 800° C. or higher and 1,000° C. or lower. When the glass fibers have the properties described above, the intermediate layer can suitably achieve a desired function. Note that, in the case where a glass cloth is used in the present invention, the values of the properties are not limited to the above ranges of the numerical values.

Voids or a foamed layer may be formed in at least any of the fluororesin layer, the intermediate layer, an interface between the conductor layer and the fluororesin layer, and an interface between the fluororesin layer and the intermediate layer. When voids or a foamed layer is present in this manner, the dielectric constant can be reduced as a whole.

The fluororesin is preferably cross-linked, and a chemical bond between the fluororesin layer and the conductor layer is preferably formed by irradiation with ionizing radiation. Specifically, the chemical bond between the fluororesin layer and the conductor layer may be formed by a thermal radical reaction in vacuum, but the chemical bond is preferably formed by irradiation with ionizing radiation because the reaction is accelerated. Thus, the bonding force between the fluororesin layer and the conductor layer can be improved (chemically bonded) easily and reliably by irradiation with ionizing radiation. Furthermore, by cross-linking a fluororesin in this step, melting and flow of the fluororesin can be suppressed at a high temperature equal to or higher than the melting point of the fluororesin. Therefore, in the case where a fluororesin base including the above fluororesin is used as a wiring board, heat resistance can be improved.

### Details of Embodiments of Present Invention

A metal-resin composite body of the present invention, a method for producing the metal-resin composite body, and a tape electrical wire and a flexible printed circuit board that serve as wiring materials of the present invention will now be described with reference to the drawings.

### [Metal-Resin Composite Body]

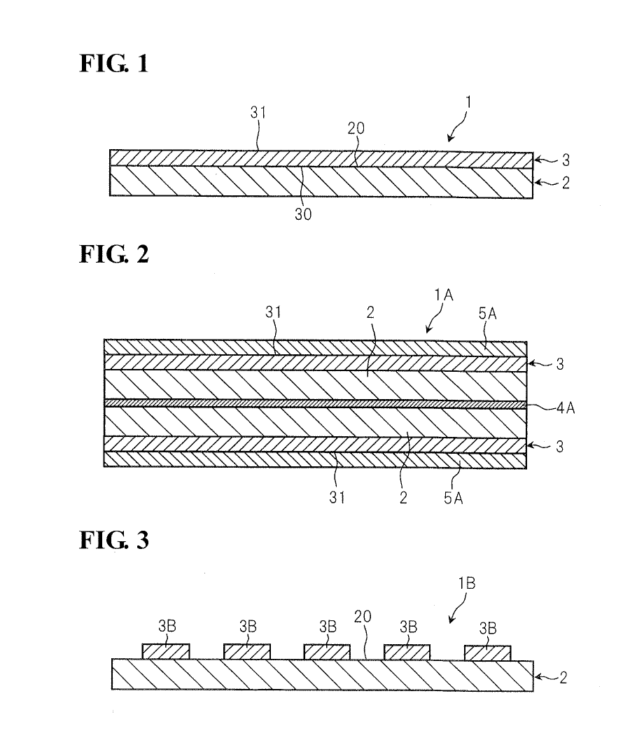

A metal-resin composite body 1 illustrated in FIG. 1 includes a synthetic resin portion 2 and a base portion 3 that is bonded to one surface 20 of the synthetic resin portion 2 (surface to which the base portion 3 is to be bonded).

### <Synthetic Resin Portion>

The synthetic resin portion 2 supports the base portion 3 and is formed in the form of a sheet. The synthetic resin portion 2 contains a fluororesin as a main component, and other optional components as required. The synthetic resin portion 2 may have insulating properties and flexibility in accordance with the use thereof.

The term “fluororesin” refers to a resin in which at least one hydrogen atom bonded to a carbon atom constituting a repeating unit of a polymer chain is substituted with a fluorine atom or an organic group having a fluorine atom (hereinafter may be referred to as “fluorine atom-containing group”). The fluorine atom-containing group is a group in which at least one hydrogen atom in a straight-chain or branched organic group is substituted with a fluorine atom. Examples thereof include fluoroalkyl groups, fluoroalkoxy groups, and fluoropolyether groups.

The term “fluoroalkyl group” means an alkyl group in which at least one hydrogen atom is substituted with a fluorine atom and covers a “perfluoroalkyl group”. Specifically, the term “fluoroalkyl group” covers a group in which all hydrogen atoms of an alkyl group are substituted with fluorine atoms, a group in which all hydrogen atoms other than one hydrogen atom at an end of an alkyl group are substituted with fluorine atoms, etc.

The term “fluoroalkoxy group” means an alkoxy group in which at least one hydrogen atom is substituted with a fluorine atom and covers a “perfluoroalkoxy group”. Specifically, the term “fluoroalkoxy group” covers a group in which all hydrogen atoms of an alkoxy group are substituted with fluorine atoms, a group in which all hydrogen atoms other than one hydrogen atom at an end of an alkoxy group are substituted with fluorine atoms, etc.

The term “fluoropolyether group” refers to a monovalent group having a plurality of alkylene oxide chains as a repeating unit and having an alkyl group or a hydrogen atom at an end thereof, the monovalent group having a group in which at least one hydrogen atom in the alkylene oxide chains and/or the alkyl group or hydrogen atom at the end is substituted with a fluorine atom. The term “fluoropolyether group” covers a “perfluoropolyether group” having a plurality of perfluoroalkylene oxide chains as a repeating unit.

Examples of the fluororesin preferably include tetrafluoroethylene/hexafluoropropylene copolymers (FEP), tetrafluoroethylene/perfluoroalkyl vinyl ether copolymers (PFA), polytetrafluoroethylene (PTFE), and tetrafluoroethylene/perfluorodioxole copolymers (TFE/PDD). Furthermore, polyvinylidene fluoride, polychlorotrifluoroethylene, chlorotrifluoroethylene/ethylene copolymers, polyvinyl fluoride, fluororesins (THV) obtained from three monomers of tetrafluoroethylene, hexafluoropropylene, and vinylidene fluoride, and fluoroelastomers are also preferably used.

The dimensions of the synthetic resin portion 2 are appropriately determined in accordance with the use etc. However, in the case where the metal-resin composite body 1 has flexibility, the lower limit of the thickness of the synthetic resin portion 2 may be 1 μm, preferably 5 μm, more preferably 7.5 μm, and still more preferably 10 μm. When the thickness is less than the lower limit, sufficient rigidity may not be ensured. On the other hand, the upper limit of the thickness of the synthetic resin portion 2 may be 5,000 μm, preferably 50 μm, more preferably 40 μm, and still more preferably 35 μm. When the thickness is larger than the upper limit, sufficient flexibility may not be ensured.

### (Other Optional Components)

Examples of the other optional components include a flame retardant aid, a pigment, antioxidant, a reflection-imparting agent, a masking agent, a lubricant, a process stabilizer, a plasticizer, and a foaming agent.

Various publicly known flame retardants can be used. Examples thereof include halogen-based flame retardants such as bromine-based flame retardants and chlorine-based flame retardants.

Various publicly known flame retardant aids can be used. An example thereof is antimony trioxide.

Various publicly known pigments can be used. An example thereof is titanium oxide.

Various publicly known antioxidants can be used. Examples thereof include phenol-based antioxidants.

Various publicly known reflection-imparting agents can be used. An example thereof is titanium oxide.

### <Base Portion>

The base portion 3 is bonded to the entire one surface 20 of the synthetic resin portion 2. The base portion 3 is formed in the form of a film, a sheet, or a foil using a metal material. Examples of the method for forming the base portion 3 include application or (for example, screen or ink-jet) printing of a foil, a wire rod, or fine particles (including nanoparticles). Examples of the metal material include conductive materials such as copper, aluminum, iron, nickel, and stainless. Among these, copper is preferred. A base portion formed by a plating treatment such as tin plating or nickel plating may also be used as the base portion 3. However, the metal material is not necessarily a conductive material depending on the application of the metal-resin composite body 1.

The base portion 3 preferably includes a rustproofing layer formed on one surface 30 thereof (surface to be bonded to the synthetic resin portion 2). This rustproofing layer suppresses a decrease in adhesiveness due to oxidation of the one surface 30 of the base portion 3. The rustproofing layer preferably contains an oxide of cobalt, chromium, or copper, and more preferably cobalt oxide. The rustproofing layer may be formed as a single layer or a plurality of layers. In the case where the rustproofing layer is formed as a single layer, the rustproofing layer is preferably composed of cobalt oxide. The rustproofing layer may be formed as a plating layer. This plating layer is formed as a single metal plating layer or an alloy plating layer. The metal constituting the single metal plating layer is preferably cobalt. Examples of the alloy constituting the alloy plating layer include cobalt-molybdenum, cobalt-nickel-tungsten, and cobalt-nickel-germanium.

The lower limit of the thickness of the rustproofing layer is preferably 0.5 nm, more preferably 1 nm, and still more preferably 1.5 nm. When the thickness is less than the lower limit, oxidation of the one surface 30 (bonding surface) of the base portion 3 may not be sufficiently suppressed. On the other hand, the upper limit of the thickness is preferably 50 nm, more preferably 40 nm, and still more preferably 35 nm. When the thickness exceeds the upper limit, an effect that is appropriate to an increase in the thickness may not be obtained.

A silane coupling agent which has a functional group containing a N atom or a S atom (hereinafter may be referred to as “reactive functional group”), such as an amino group or a sulfide group, which is a reactive functional group, is present in the vicinity of an interface between the base portion 3 and the synthetic resin portion 2. This silane coupling agent increases adhesiveness between the synthetic resin portion 2 and the base portion 3. A hydrolyzable group (such as OCH₃, OC₂H₅, or OCOCH₃) of the silane coupling agent is hydrolyzed and is bonded on the one surface 30 side (the one surface 30 of the base portion 3 or the rustproofing layer) of the base portion 3. The silane coupling agent is thereby fixed on the one surface 30 side of the base portion 3. It is believed that, on the other hand, the silane coupling agent is fixed to the synthetic resin portion 2 with the reactive functional group of the silane coupling agent. Specifically, it is believed that the silane coupling agent is fixed to the synthetic resin portion 2 as a result of chemical bonding between a radical portion of the fluororesin, which is a main component of the synthetic resin portion 2, and the reactive functional group of the silane coupling agent. It is believed that since the silane coupling agent is present in the vicinity of the interface between the base portion 3 and the synthetic resin portion 2 in this manner, adhesiveness between the synthetic resin portion 2 and the base portion 3 is enhanced. The silane coupling agent is believed to be present between the synthetic resin portion 2 and the base portion 3 so as to have a thickness on the order of Angstroms (Å). It is believed that, therefore, the metal-resin composite body 1 does not substantially affect properties of the one surface 31 of the base portion 3, and thus degradation of high-frequency characteristics due to the silane coupling agent does not occur.

Examples of the silane coupling agent which has a functional group containing a N atom include aminoalkoxysilanes, ureidoalkoxysilanes, and derivatives thereof.

Examples of aminoalkoxysilanes include 3-aminopropyltrimethoxysilane, 3-aminopropyltriethoxysilane, N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, and N-phenyl-3-aminopropyltrimethoxysilane.

Examples of the derivatives of aminoethoxysilanes include ketimines such as 3-triethoxysilyl-N-(1,3-dimethyl-butylidene)propylamine, and salts of a silane coupling agent such as an acetate of N-(vinylbenzyl)-2-aminoethyl-3-aminopropyltrimethoxysilane.

Examples of ureidoalkoxysilanes include 3-ureidopropyltriethoxysilane, 3-ureidopropyltrimethoxysilane, and γ-(2-ureidoethyl)aminopropyltrimethoxysilane.

Examples of the silane coupling agent which has a functional group containing a S atom include mercaptoalkoxysilanes, sulfide alkoxysilanes, and derivatives thereof.

Examples of mercaptoalkoxysilanes include 3-mercaptopropyltrimethoxysilane, 3-mercaptopropyl(dimethoxy)methylsilane, and mercaptoorganyl(alkoxysilanes).

Examples of sulfide alkoxysilanes include bis(3-(triethoxysilyl)propyl)tetrasulfide and bis(3-(triethoxysilyl)propyl)disulfide.

The silane coupling agent may be a silane coupling agent to which a modifying group is introduced. The modifying group is preferably a phenyl group.

Among these, 3-aminopropyltriethoxysilane, N-phenyl-3-aminopropyltrimethoxysilane, 3-ureidopropyltriethoxysilane, 3-mercaptopropyltrimethoxysilane, and bis(3-(triethoxysilyl)propyl)tetrasulfide are preferable as the silane coupling agent.

The peeling strength of the base portion 3 to the synthetic resin portion 2 is preferably 3 N/cm or more, more preferably 4.5 N/cm or more, and still more preferably 6 N/cm or more in terms of peel strength. When the peeling strength is equal to or more than the above values, the metal-resin composite body 1 can be suitably used as a flexible substrate such as a tape electrical wire or a flexible printed circuit board.

The dimensions of the base portion 3 are appropriately determined in accordance with the use etc. as in the synthetic resin portion 2. However, in the case where the metal-resin composite body 1 has flexibility, the lower limit of the thickness of the base portion 3 may be 1 μm, and is preferably 6 more preferably 10 still more preferably 15 μm, and particularly preferably 18 μm. When the thickness is less than the lower limit, rigidity of the base portion 3 may not be ensured. On the other hand, the upper limit of the thickness of the base portion 3 may be 5,000 and is preferably 400 μm, more preferably 40 μm, and still more preferably 30 μm. When the thickness exceeds the upper limit, sufficient flexibility may not be ensured.

### [Method for Producing Metal-Resin Composite Body]

A method for producing a metal-resin composite body 1 includes

(1) a step (application step) of applying a composition containing a silane coupling agent which has a functional group containing a N atom or a S atom (hereinafter may be referred to as “coupling agent-containing composition”) onto a part of an outer surface including at least one surface 30 of a metal base portion 3,
(2) a step (drying step) of drying the composition,
(3) a step (bonding step) of bonding a synthetic resin portion 2 containing a fluororesin as a main component to at least the composition-applied surface (one surface 30) of the base portion 3, and as required, before the application step, a step (rustproofing layer formation step) of forming a rustproofing layer on at least the one surface 30 of the base portion 3.

### <Rustproofing Layer Formation Step>

The rustproofing layer formation step is performed by applying a rustproofing solution containing a metal ion onto at least one surface of the base portion 3, and then drying the rustproofing solution. The metal ion is preferably a cobalt ion, a chromium ion, and a copper ion, and more preferably a cobalt ion. Various publicly known methods can be employed as the method for applying a rustproofing solution. Examples thereof include a method in which the base portion 3 is immersed in a rustproofing solution and a method in which a rustproofing solution is applied to the base portion 3. The drying of the rustproofing solution may be air drying or forced drying. By drying the rustproofing solution in this manner, a rustproofing layer composed of a metal oxide derived from the metal ion in the rustproofing solution is formed on the at least one surface 30 of the base portion 3.

The rustproofing layer formation step may be performed by a plating method such as a water-soluble electrolytic plating method. In the case where a plating method is employed, the rustproofing layer is formed as a single metal plating layer or an alloy plating layer and preferably formed so as to contain cobalt.

### <(1) Application Step>

The application step is performed in order to bond the silane coupling agent to a base portion 3. In the case where a rustproofing layer is formed on the base portion 3, this application step is performed after the rustproofing layer formation step.

Examples of the method for applying a coupling agent-containing composition in the application step include, but are not particularly limited to, a method in which the base portion 3 is immersed in a coupling agent-containing composition and a method in which a coupling agent-containing composition is applied onto the base portion 3. The method in which the base portion 3 is immersed in a coupling agent-containing composition is preferable.

In the case of employing the method in which the base portion 3 is immersed in a coupling agent-containing composition, the temperature of the coupling agent-containing composition is 20° C. to 40° C., and the immersion time is 10 to 30 seconds.

### (Coupling Agent-Containing Composition)

The coupling agent-containing composition contains the above silane coupling agent and a solvent and may contain an optional component as long as the effects of the present invention are not impaired.

(Silane Coupling Agent which has Functional Group Containing N Atom or S Atom)

The silane coupling agents exemplified above can be used as the silane coupling agent which has a functional group containing a N atom or a S atom. Among the silane coupling agents, 3-aminopropyltriethoxysilane, N-phenyl-3-aminopropyltrimethoxysilane, 3-ureidopropyltriethoxysilane, 3-mercaptopropyltrimethoxysilane, and bis(3-(triethoxysilyl)propyl)tetrasulfide, all of which have a high effect of improving adhesiveness, are preferable.

The lower limit of the content of the silane coupling agent in the coupling agent-containing composition is 0.1% by mass, and more preferably 0.5% by mass. When the content of the silane coupling agent is less than the lower limit, adhesiveness between the synthetic resin portion 2 and the base portion 3 may not be sufficiently enhanced. On the other hand, the upper limit of the content of the silane coupling agent is preferably 5% by mass, more preferably 3% by mass, and still more preferably 1.5% by mass. When the content of the silane coupling agent exceeds the upper limit, the silane coupling agent easily aggregates, and it may become difficult to prepare the coupling agent-containing composition.

### (Solvent)

The solvent is not particularly limited as long as the solvent can dissolve the silane coupling agent. Examples thereof include alcohols such as methanol and ethanol, toluene, hexane, and water. However, from the viewpoint of storage stability, the solvent for ethoxysilane coupling agents is preferably ethanol, and the solvent for methoxysilane coupling agents is preferably methanol.

### (Optional Components)

Examples of the optional components include an antioxidant, a viscosity modifier, and a surfactant. Examples of the antioxidant include iron, sugars, reductones, sodium sulfite, and ascorbic acid (vitamin C).

### <(2) Drying Step>

The drying step may be conducted by air drying or forced drying, but air drying is preferable.

After the coupling agent-containing composition is dried, a heating treatment of the base portion 3 is preferably conducted. By conducting the heating treatment, the silane coupling agent can be more reliably fixed to the one surface 30 of the base portion 3. The heating treatment may be conducted by, for example, heating in a thermostatic chamber at 100° C. to 130° C. for 1 to 10 minutes.

### <(2) Bonding Step>

The bonding step is conducted by, for example, heating the base portion 3 and the synthetic resin portion 2 under pressure in a state where the base portion 3 is placed on the one surface 20 of the synthetic resin portion 2. By appropriately selecting the conditions for the heating under pressure, an end or a side chain of a fluororesin, which is a main component of the synthetic resin portion 2, is decomposed to convert a part of the fluororesin into radicals.

This bonding step can be conducted using a publicly known thermal press machine. The bonding step is preferably conducted by a vacuum press under a low-oxygen concentration, for example, under a nitrogen atmosphere. By conducting the bonding step under a low-oxygen concentration, oxidation of the one surface 30 (bonding surface) of the base portion 3 is suppressed, and a decrease in the adhesive force can be suppressed.

The heating temperature is preferably equal to or higher than a crystalline melting point of the fluororesin, which is a main component of the synthetic resin portion 2, more preferably equal to or higher than a temperature 30° C. higher than the crystalline melting point, and still more preferably equal to or higher than a temperature 50° C. higher than the crystalline melting point. For example, in the case where the main component of the synthetic resin portion 2 is FEP, since the crystalline melting point of the FEP is about 270° C., the heating temperature is preferably 270° C. or higher, more preferably 300° C. or higher, and still more preferably 320° C. or higher. By heating the synthetic resin portion 2 at such a heating temperature, radicals of the fluororesin can be effectively generated. However, when the heating temperature is excessively high, the fluororesin may be degraded. Accordingly, the upper limit of the heating temperature is preferably 600° C. or lower, and more preferably 500° C. or lower.

In addition to the above heating under pressure, other publicly known radical generation methods, for example, electron beam irradiation and the like may be used in combination. Examples of the electron beam irradiation and the like include an electron beam irradiation treatment and a γ-ray irradiation treatment. By using electron beam irradiation and the like in combination, radicals of a fluororesin can be more effectively generated. Thus, the reliability of the bonding between the one surface 20 of the synthetic resin portion 2 and the base portion 3 can be further increased.

In the case where a wiring board is produced, a circuit can be formed by removing at least a part of a conductive layer. An example of the method for removing a conductive layer is a dissolution method.

### <Advantages>

In the metal-resin composite body 1, since the silane coupling agent which has a functional group containing a N atom or a S atom is present in the vicinity of the interface between the synthetic resin portion 2 and the base portion 3, adhesiveness between the synthetic resin portion 2 and the base portion 3 can be increased. Although the reason for this is not clear, it is believed that while a hydrolyzable group of the coupling agent is fixed to the base portion 3, the functional group of the silane coupling agent, the functional group containing a N atom or a S atom, such as an amino group or a sulfide group, is chemically bonded to a radical portion of a fluororesin, which is a main component of the synthetic resin portion 2, thereby improving the adhesiveness.

In addition, according to the metal-resin composite body 1, since the adhesiveness is enhanced by the presence of the silane coupling agent in the vicinity of the interface between the synthetic resin portion 2 and the base portion, it is possible to suppress disadvantages of the existing methods such as the method in which a primer layer is formed between a metal base and a covering layer composed of a fluororesin polymer, and the method in which a surface of a metal base is roughened. Specifically, an increase in the relative dielectric constant of the synthetic resin portion 2 can be suppressed. In addition, when the metal-resin composite body is applied to a wiring material, an increase in the transmission loss due to an increase in resistance attenuation or leakage attenuation can be suppressed. Therefore, the metal-resin composite body 1 can provide a wiring material having good high-frequency signal transmission characteristics.

A fluororesin base 101 which is another embodiment of the present invention will be described with reference to FIG. 8.

The fluororesin base 101 includes a fluororesin layer 102 formed of a fluororesin and a modified layer 103 formed on at least a part of a surface of the fluororesin layer 102. Herein, the term “surface of a fluororesin layer 102” refers to an entire peripheral surface of the fluororesin layer 102, the entire peripheral surface including one surface of the fluororesin layer 102 and another surface opposite to the one surface. FIG. 8 illustrates a structure in which the modified layer 103 is formed over the entire surface of one surface. However, this structure is an example. The region where the modified layer 103 is formed may be a part of the one surface. Alternatively, the region where the modified layer 103 is formed may be the whole of the two surfaces or a part of each of the two surfaces.

In the case where a fluororesin base (base that does not include a conductive wiring) is produced, a laminate of a metal base and a fluororesin material is immersed in an etchant. As a result, the metal base is completely removed.

When a copper material is used as a conductive layer, copper constituting the metal base of the laminate is dissolved with an etchant. An etchant containing iron chloride, having a specific gravity of 1.31 g/cm³ or more and 1.33 g/cm³ or less, and a free hydrochloride concentration of 0.1 mol/L or more and 0.2 mol/L or less is preferably used. In the case where the etchant is used, regarding etchant conditions, the temperature is preferably 30° C. or higher and 45° C. or lower, and the immersion time is preferably 30 seconds or more and 2 minutes or less. According to these conditions, a copper foil is removed, and removal of a modified layer from a fluororesin material can be suppressed.

It is believed that the following change is caused in the modified layer as a result of the removal of the metal base by dissolution. Some of functional groups of a silane coupling agent are chemically bonded to the metal base due to thermocompression bonding between the metal base and the fluororesin material. It is believed that, since the chemically bonded portions are exposed to the etchant as a result of the dissolution of the metal base, the chemically bonded portions are returned to the original functional groups by hydrolysis or changed to other functional groups having a hydroxyl group or the like.

The modified layer in the present embodiment preferably has the following etching resistance. Specifically, preferably, the modified layer is not removed by an etching treatment including immersion using an etchant containing iron chloride, having a specific gravity of 1.31 g/cm³ or more and 1.33 g/cm³ or less, and a free hydrochloride concentration of 0.1 mol/L or more and 0.2 mol/L or less at 45° C. or lower for two minutes or less. Herein, the phrase “modified layer is not removed” means that hydrophilicity is not lost, and that the contact angle with water does not exceed 90° in a portion where the modified layer is provided. In some cases, very small portions that exhibit hydrophobicity are generated in a spotted manner by an etching treatment in a region where the modified layer is formed. However, when the region exhibits hydrophilicity as a whole, it is assumed that this state maintains hydrophilicity.

The modified layer preferably has etching resistance to an etchant containing copper chloride. It has been confirmed that when a modified layer has the etching resistance to an etchant containing iron chloride, this modified layer has the etching resistance to an etchant containing copper chloride.

The portion where the modified layer is formed preferably has a contact angle with pure water of 90° or less. This is because when the contact angle is larger than 90°, the adhesive strength (i.e., peeling strength) of the resulting adhesion product decreases. More preferably, the contact angle in the portion where the modified layer is formed is 80° or less. Herein, the contact angle is a value measured with a contact angle meter (manufactured by ERMA Inc., G-I-1000).

Furthermore, in the portion where the modified layer is formed, adhesion energy between the surface of the modified layer and water is preferably 50 dyne/cm or more. This value is higher than that of existing PTFE. That is, according to this property, adhesive properties become higher than those of existing fluororesins.

The thickness of the modified layer is preferably 400 nm or less on average, and more preferably 200 nm or less on average. The thickness of the modified layer is a distance measured with an optical interference film thickness meter, X-ray photoelectron spectroscopy (XPS), or an electron microscope. By specifying the thickness of the modified layer in this manner, when a fluororesin base is used as a wiring board, it is possible to suppress a decrease in the high-frequency characteristics due to the thickness of the modified layer as compared with the case where the thickness of the modified layer is more than 400 nm on average.

The modified layer has a hydrophilic functional group. This functional group is bonded to a Si atom constituting a siloxane bond. Since the modified layer has a hydrophilic functional group, the fluororesin base has hydrophilicity, and wettability of the surface thereof improves. Therefore, in the case where the fluororesin base is surface-treated in a polar solvent, the treatment speed and uniformity of the surface treatment (absence of spots caused by the treatment) can be improved.

The functional group is preferably one that is active to adhesives, covering resins, covering members, and ink that adhere to the fluororesin base.

Examples of the adhesives to be applied onto the fluororesin base include conductive adhesives, anisotropic conductive adhesives, adhesives of coverlay films, and prepreg resins for bonding substrates to each other. Examples of resins constituting the adhesives include epoxy resins, polyimide resins, unsaturated polyester resins, saturated polyester resins, butadiene resins, acrylic resins, polyamide resins, polyolefin resins, silicone resins, fluororesins, urethane resins, PEEK, PAI, polyethersulfone (PES), syndiotactic polystyrene (SPS), and resins containing at least one of these resins. These resins may be cross-liked by an electron beam, a radical reaction, or the like, and the resins obtained in this manner may be used as the materials of the adhesives.

The peeling strength of a polyimide sheet (sheet used as a coverlay film) having an epoxy resin adhesive can be determined to a particular value or more in accordance with selection of the functional group. From the viewpoint of reliability required in a circuit module in which this type of fluororesin base is used, the peeling strength of the polyimide sheet (sheet used as a coverlay film) having an epoxy resin adhesive is preferably 1.0 N/cm or more. More preferably, this peeling strength is 5.0 N/cm or more.

In the fluororesin base, a surface roughness of the modified layer is preferably specified. For example, a mean surface roughness Ra of this region is determined to 4 or less. More preferably, the mean surface roughness Ra of this region is determined to 2 μm or less. Herein, the term “mean surface roughness” refers to an arithmetical mean roughness (JIS B 0601 (2001)). By specifying the surface roughness of the modified layer in this manner, when a fluororesin base is used as a circuit board, the circuit board can have good high-frequency characteristics. For example, by determining the mean surface roughness Ra of the modified layer to 4 μm or less, signal transmission loss of a high-frequency signal in a conductive wiring on the modified layer can be reduced as compared with the case where the mean surface roughness Ra of the modified layer is determined to more than 4 μm.

The fluororesin base having the above structure is used as, for example, an insulating layer of a printed circuit board. In this case, a covering member, a covering resin, an adhesive, ink, and the like are attached, as an adhesion product, to the fluororesin base. An example of the covering member is a coverlay film. The covering member is formed of, for example, a polyimide resin, an epoxy resin, SPS, a fluororesin, a cross-linked polyolefin, a silicone resin, or the like.

The fluororesin base having the above structure can also be used as a coverlay film of other printed circuit boards. For example, the fluororesin base having the above structure may be used as a coverlay film on a printed circuit board including a fluororesin base functioning as an insulating layer. Specifically, a low-dielectric material is used as both the insulating layer and the covering member. According to this structure, a high-frequency circuit module having a low signal transmission loss can be obtained. In this case, since each of the insulating layer and the coverlay film is composed of a fluororesin, the insulating layer and the coverlay film can be bonded to each other by thermofusion. For example, this pressing is conducted at a temperature of 180° C. for 20 minutes or more and 30 minutes or less at 3 MPa or more and 4 MPa or less.

In addition, the fluororesin base having the above structure can also be used as a coverlay film on a printed circuit board including a polyimide or a liquid crystal polymer as an insulating layer. In this case, the printed circuit board and the fluororesin base are bonded with an adhesive therebetween. Since the fluororesin base includes a modified layer, the printed circuit board and the fluororesin base can be bonded to each other with an existing adhesive (for example, an epoxy resin or the like) by using the surface of the modified layer as a bonding surface.

The thickness of the fluororesin base functioning as a coverlay film is preferably 3.0 μm or more and 100 μm or less. More preferably, the thickness of the fluororesin base is 6.0 μm or more and 55 μm or less. When the thickness is less than 3.0 μm, the fluororesin base may tear in the production process due to a decrease in the tensile strength. When the thickness is more than 100 flexibility decreases.

### OTHER EMBODIMENTS

It is to be understood that the embodiments disclosed herein are only illustrative and are not restrictive in all respects. The scope of the present invention is not limited to the configurations of the above embodiments but is defined by the claims. It is intended that the scope of the present invention includes equivalents of the claims and all modifications within the scope of the claims. Embodiments of the present invention can be carried out by modifying as described below, as typified by the examples illustrated in FIGS. 2 and 3.

FIG. 2 is a schematic cross-sectional view illustrating a metal-resin composite body according to another embodiment of the present invention. In FIG. 2, components the same as those of the metal-resin composite body 1 illustrated in FIG. 1 are assigned the same reference numerals, and an overlapping description is omitted.

A metal-resin composite body 1A illustrated in FIG. 2 is formed as a laminate including a cushioning material 5A, a base portion 3, a synthetic resin portion 2, a reinforcing layer 4A, a synthetic resin portion 2, a base portion 3, and a cushioning material 5A. This laminate is formed by, for example, heat-pressing in a state where the cushioning material 5A, the base portion 3, the synthetic resin portion 2, the reinforcing layer 4A, the synthetic resin portion 2, the base portion 3, and the cushioning material 5A are stacked.

The reinforcing layer 4A prevents warpage of the synthetic resin portions 2. The reinforcing layer 4A is laminated between the pair of synthetic resin portions 2. That is, the reinforcing layer 4A is formed on the side opposite to the base portion 3 (metal layer) in each of the synthetic resin portions 2. Examples of the material of the reinforcing layer 4A include, but are not particularly limited to, high-strength heat-resistant engineering plastic's such as polyimide resins, and glass fibers.

The cushioning materials 5A each function as a heat-insulating material against heating, a buffer material against pressurization, and the like when the metal-resin composite body 1A is formed by heat-pressing. An example of the material of the cushioning materials 5A is carbon felt but is not particularly limited.

Instead of the formation of the reinforcing layer 4A or in addition to the formation of the reinforcing layer 4A, a reinforcing material may be mixed in the synthetic resin portions 2. The reinforcing material is a material that can control strength and thermal expansion/shrinkage without impairing high-frequency characteristics (ε, tan δ) of the entire metal-resin composite body 1A. For example, hollow silica glass beads can be used.

Here, high-frequency waves are concentrated by a surface layer effect mainly in the vicinity of a metal (base portion 3) that is in contact with a dielectric (synthetic resin portion 2). Therefore, from the viewpoint of high-frequency characteristics, it is important that the surface of each of the base portions 3 be smooth and that an adhesive layer be not substantially present between the base portion 3 and the corresponding synthetic resin portion 2.

On the other hand, the metal-resin composite body 1A is not substantially affected by the smoothness of the surface of each of the base portions 3 because the reinforcing layer 4A is provided on the side opposite to the base portion 3 in the synthetic resin portion 2 and/or a reinforcing material such as a hollow silica glass bead is mixed in the synthetic resin portion 2. Furthermore, since a silane coupling agent is present between the base portion 3 and the synthetic resin portion 2 so as to have a thickness on the order of Angstroms (Å), an adhesive layer is not substantially present between the base portion 3 and the synthetic resin portion 2. Therefore, in the metal-resin composite body 1A, adhesiveness between each of the synthetic resin portions 2 and the corresponding base portion 3 can be increased by the reinforcing layer 4A, the reinforcing material, and the silane coupling agent while high-frequency characteristics of the metal-resin composite body 1A are not substantially affected and warpage of the synthetic resin portions 2 is prevented.

In the metal-resin composite body 1 illustrated in FIG. 1, the base portion 3 is formed over the entire one surface 20 of the synthetic resin portion 2. Alternatively, as in a metal-resin composite body 1B illustrated in FIG. 3, a plurality of rectangular base portions 3B may be partly bonded to one surface 20 of a synthetic resin portion 2.

The base portion of the metal-resin composite body is not necessarily formed only on one surface of the synthetic resin portion as illustrated in the metal-resin composite bodies 1 and 1B that are illustrated in FIGS. 1 and 3, respectively. The base portion may be formed on both surfaces of the synthetic resin portion.

The metal-resin composite body may be formed by fixing the silane coupling agent to the synthetic resin portion, and then bonding the base portion and the synthetic resin portion to each other instead of fixing the silane coupling agent to the base portion, and then bonding the base portion and the synthetic resin portion to each other.

The form of the base portion of the metal-resin composite body is not limited to the sheet shape and the rectangular shape that are illustrated in FIGS. 1 to 3. For example, the form of the base portion may be a cube, a wire rod having a circular cross-sectional shape, or a wire bundle obtained by stranding a plurality of wire rods. The form of the synthetic resin portion may be changed in accordance with the form of the base portion and use of the metal-resin composite body. For example, the synthetic resin portion may be a portion that covers an entire outer circumference of a wire rod having a circular cross-sectional shape, as in an insulated electrical wire. Alternatively, the synthetic resin portion may be a portion that selectively covers a part or the entirety of outer surfaces of a synthetic resin block.

The formation of the rustproofing layer of the metal-resin composite body is optional, and the rustproofing layer may be omitted.

### [Wiring Material]

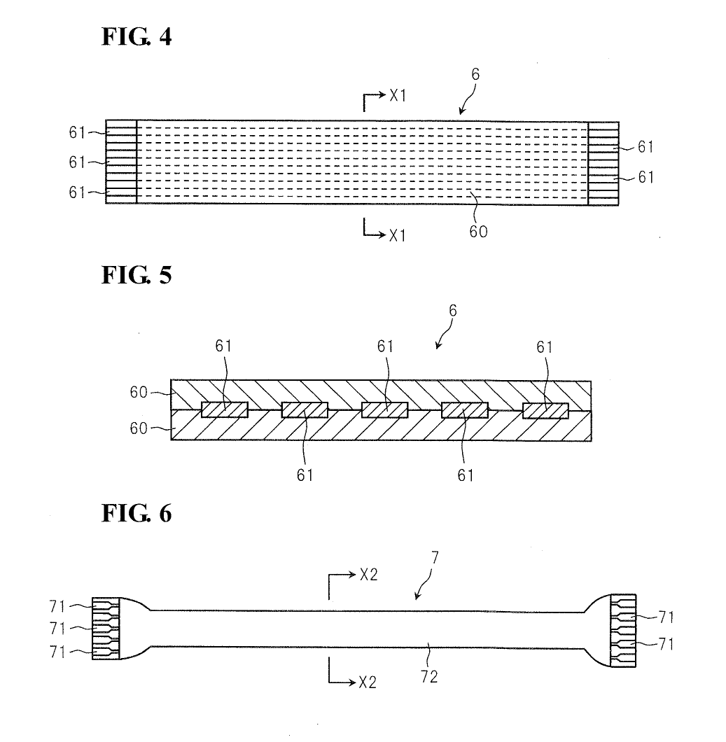

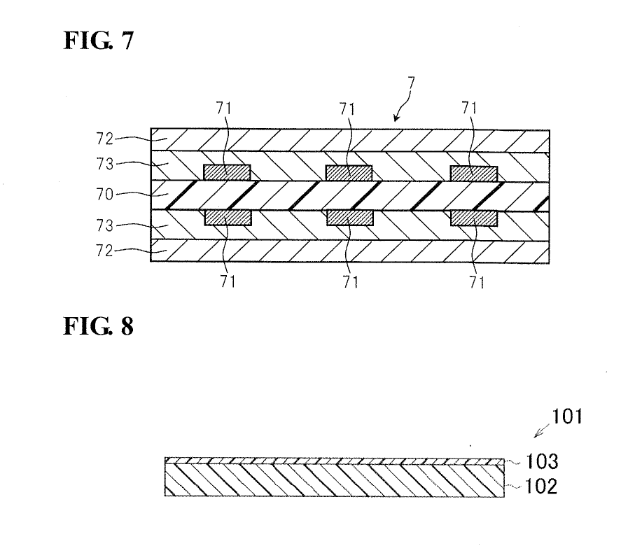

A wiring material of the present invention includes the metal-resin composite body and can be constituted as a tape electrical wire illustrated in FIGS. 4 and 5 or a flexible printed circuit board illustrated in FIGS. 6 and 7.

### <Tape Electrical Wire>

A tape electrical wire 6 illustrated in FIGS. 4 and 5 is used as a flexible flat cable (FFC) or the like. The tape electrical wire 6 includes a pair of synthetic resin portions 60 having flexibility and a plurality of base portions 61 formed between the synthetic resin portions 60.

The pair of synthetic resin portions 60 is formed as a band having a long dimension in a direction (longitudinal direction corresponding to the left-right direction in FIG. 4). Each of the synthetic resin portions 60 is the same as the synthetic resin portion 2 of the metal-resin composite body 1 in FIG. 1 except for the appearance shape. The pair of synthetic resin portions 60 is preferably bonded to each other with an adhesive layer therebetween.

The plurality of base portions 61 are arranged in parallel in a lateral direction (the top-bottom direction in FIG. 4). Each of the base portions 61 is a rectangular conductor having a long rectangular cross-sectional shape. A rustproofing layer is preferably provided on both surfaces of each of the base portions 61. This rustproofing layer is the same as the rustproofing layer of the metal-resin composite body 1 in FIG. 1. The base portion 61 is formed of the same metal material as the base portion 3 of the metal-resin composite body 1 in FIG. 1. The thickness of the base portion 61 is determined in accordance with, for example, the amount of current used. For example, when the base portion 61 is in the form of a foil, the thickness is 20 μm or more and 50 μm or less.

A silane coupling agent which has a functional group containing a N atom or a S atom is present in the vicinity of an interface between each surface (surface to be bonded to a synthetic resin portion 60) of each base portion 61 and the synthetic resin portion 60. The same silane coupling agent as the silane coupling agent which has a functional group containing a N atom or a S atom and used in the metal-resin composite body 1 in FIG. 1 is used and is fixed to the base portion 61 by the same method as that used in the metal-resin composite body 1 in FIG. 1.

This tape electrical wire 6 can be produced by interposing a plurality of base portions 61, in which the silane coupling agent is fixed to both surfaces thereof, between a pair of synthetic resin portions 60, and conducting heating under pressure.

### <Flexible Printed Circuit Board>

A flexible printed circuit board 7 illustrated in FIGS. 6 and 7 includes a synthetic resin portion 70 having flexibility, a plurality of base portions 71, and cover films 72.

The synthetic resin portion 70 is formed as a band having a long dimension in a direction (longitudinal direction corresponding to the left-right direction in FIG. 6). The synthetic resin portion 70 is the same as the synthetic resin portion 2 of the metal-resin composite body 1 in FIG. 1 except for the appearance shape. The thickness of the synthetic resin portion 70 is, for example, 10 μm or more and 30 μm or less. When the thickness of the synthetic resin portion 70 is smaller than the above range, strength of the synthetic resin portion 70 may be insufficient. On the other hand, when the thickness of the synthetic resin portion 70 is larger than the above range, the flexible printed circuit board 7 may be excessively thick.

The base portions 71 are provided on both surfaces of the synthetic resin portion 70. Each of the base portions 71 is formed of the same metal material as the base portion 3 of the metal-resin composite body 1 in FIG. 1. The thickness of the base portion 71 is determined in accordance with, for example, the amount of current used and is, for example, 10 μm or more and 30 μm or less.

A silane coupling agent which has a functional group containing a N atom or a S atom is present in the vicinity of an interface between one surface (surface to be bonded to the synthetic resin portion 70) of each base portion 71 and the synthetic resin portion 70. The silane coupling agent is fixed to the base portion 71 by the same method as that used in the metal-resin composite body 1 in FIG. 1. The same silane coupling agent as the silane coupling agent which has a functional group containing a N atom or a S atom and used in the metal-resin composite body 1 in FIG. 1 is used and is fixed to the base portion 71 by the same method as that used in the metal-resin composite body 1 in FIG. 1.

The cover films 72 are laminated on both surfaces of the synthetic resin portion 70 with adhesive layers 73 therebetween so as to cover the base portions 71. The material of the cover films 72 is not particularly limited. For example, liquid crystal polymers, polyimide resins, polyethylene terephthalate resins, and the like are preferable. Among these, liquid crystal polymers are more preferable.

The thickness of each of the cover films 72 is, for example, 10 μm or more and 30 p.m. When the thickness of the cover film 72 is smaller than the above range, insulating properties may be insufficient. On the other hand, when the thickness of the cover film 72 is larger than the above range, the flexible printed circuit board 7 may lose flexible properties.

The material of the adhesive layers 73 is not particularly limited but is preferably a material having good flexibility and good heat resistance. Examples thereof include adhesives composed of various resins such as polyimide resins, polyamide resins, epoxy resins, butyral resins, and acrylic resins. Among these, polyimide resins are preferable. The thickness of each of the adhesive layers 73 is not particularly limited but is preferably 20 μm or more and 30 μm or less. When the thickness of the adhesive layer 73 is smaller than the above range, adhesive properties may be insufficient. On the other hand, when the thickness of the adhesive layer 73 is larger than the above range, the flexible printed circuit board 7 may lose flexible properties.

### EXAMPLES

The present invention will now be described on the basis of Examples and Comparative Examples. It is to be understood that the present invention is not limited to the Examples below, the Examples can be modified or changed on the basis of the gist of the present invention, and the modifications and the changes are not excluded from the scope of the present invention.

### Example 1

First, a cobalt treatment for forming a rustproofing layer on a copper foil (base portion) having a thickness of 20 μm was conducted.

Next, the copper foil was immersed for 15 seconds in a coupling agent-containing composition at 30° C. prepared by dissolving 1% by mass of 3-aminopropyltriethoxysilane in ethanol. The coupling agent-containing composition was air-dried, and then heated in a thermostatic chamber at 110° C. for five minutes to fix the coupling agent to the copper foil.

Subsequently, a laminate serving as a metal-resin composite body was formed by stacking a cushioning material, a copper foil, a fluororesin sheet serving as a synthetic resin portion, a coper foil, and a cushioning material in that order, and conducting heat-pressing.

Carbon felt having a thickness of 5.0 mm was used as the cushioning materials.

An FEP film (“NEOFLON FEP NE-2” (manufactured by Daikin Industries, Ltd.)) having a thickness of 30 μm and a melting point of 270° C. was used as the fluororesin sheet.

The heat-pressing was conducted using a “10-TON TEST PRESS” press machine (manufactured by Morita Engineering Works Co. Ltd.). The heating temperature was 320° C., the pressurizing force was 6.0 MPa, and the pressing time was 40 minutes.

### Examples 2 to 6 and Comparative Examples 1 to 15

Laminates (metal-resin composite bodies) were prepared as in Example 1 except for the following conditions: Whether or not the cobalt treatment was performed and the type of silane coupling agent are as shown in Table I (with regard to the type of silane coupling agent, refer to Table II).

### <Evaluation>

### (Evaluation of Bonding Force)

A bonding force was evaluated by measuring, as a peel strength, a peel force of a copper foil to a fluororesin sheet in a laminate. The peel strength was measured as a bonding strength between the copper foil and the fluororesin sheet using an “Autograph AG-IS” tensile tester (manufactured by Shimadzu Corporation) in accordance with JIS K 6854-2:1999 “Adhesives-Determination of peel strength of bonded assemblies, Part 2: 180 degree peel”.

Table I shows the measurement results of the bonding force of the laminates of Examples 1 to 6 and Comparative Examples 1 to 15. In Table I, when the peel strength is 3 N/cm or more, the result is denoted by “A”. When the peel strength is less than 3 N/cm, the result is denoted by “B”.

TABLE I

| | | | Coupling agent- | | | |
|---|---|---|---|---|---|---|
| | | | containing | | | |
| | | | composition | | | |
| | | | (1 wt %) | | | |
| | Conductor | Cobalt | Coupling | | Peel test | Evaluation |
| | layer | treatment | agent | Solvent | (N/cm) | result |
| Example 1 | Copper foil | Performed | A-1 | Ethanol | 8.4 | A |
| Example 2 | Copper foil | Not performed | A-1 | Ethanol | 5.5 | A |
| Example 3 | Copper foil | Not performed | A-2 | Methanol | 8.6 | A |
| Example 4 | Copper foil | Not performed | A-3 | Ethanol | 3.1 | A |
| Example 5 | Copper foil | Not performed | A-4 | Methanol | 3.2 | A |
| Example 6 | Copper foil | Not performed | A-5 | Ethanol | 3.0 | A |
| Comparative example 1 | Copper foil | Performed | — | — | 1.2 | B |
| Comparative example 2 | Copper foil | Performed | B-1 | Ethanol | 1.8 | B |
| Comparative example 3 | Copper foil | Performed | B-2 | Methanol | 1.6 | B |
| Comparative example 4 | Copper foil | Performed | B-3 | Methanol | 1.7 | B |
| Comparative example 5 | Copper foil | Performed | B-4 | Methanol | 1.1 | B |
| Comparative example 6 | Copper foil | Not performed | — | — | 2.2 | B |
| Comparative example 7 | Copper foil | Not performed | B-1 | Ethanol | 1.5 | B |
| Comparative example 8 | Copper foil | Not performed | B-2 | Methanol | 1.8 | B |
| Comparative example 9 | Copper foil | Not performed | B-3 | Methanol | 1.3 | B |
| Comparative example 10 | Copper foil | Not performed | B-4 | Methanol | 1.7 | B |
| Comparative example 11 | Copper foil | Not performed | B-5 | Methanol | 0.9 | B |
| Comparative example 12 | Copper foil | Not performed | B-6 | Ethanol | 1.1 | B |
| Comparative example 13 | Copper foil | Not performed | B-7 | Methanol | 1.3 | B |
| Comparative example 14 | Copper foil | Not performed | B-8 | Ethanol | 1.5 | B |
| Comparative example 15 | Copper foil | Not performed | B-9 | Methanol | 2.2 | B |

TABLE II

| | | Functional | | |
|---|---|---|---|---|
| Code | Product name | group | Main component | Structure |
| A-1 | KBE-903 | Amine | 3-Aminopropyltriethoxysilane | 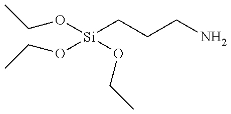 |
| A-2 | KBM-573 | | N-Phenyl-3- aminopropyltrimethoxysilane | 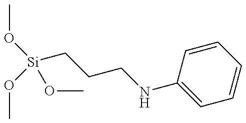 [SMILES: CO[Si](CCCNc1ccccc1)(OC)OC] |
| A-3 | KBE-585 | Ureido | 3-Ureidopropyltriethoxysilane | 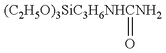 |
| A-4 | KBM-803 | Mercapto | 3-Mercaptopropyltrimethoxysilane | (CH₃O)₃SiC₃H₆SH |
| A-5 | KBE-846 | Sulfide | Bis(3-(triethoxysilyl)propyl)tetrasulfide | (C₂H₅O)₃SiC₃H₆S₄C₃H₆Si(OC₂H₅)₃ |
| B-1 | KBE-403 | Epoxy | 3-Glycidoxypropyltriethoxysilane | 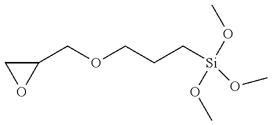 |
| B-2 | KBM-503 | Methacryl | 3-Methacryloxypropyltrimethoxysilane | 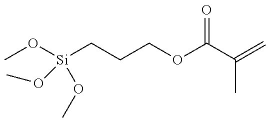 [SMILES: C=C(C)C(=O)OCCC[Si](OC)(OC)OC] |
| B-3 | KBM-7103 | Fluoro | 3,3,3-Trifluoropropyltrimethoxysilane | 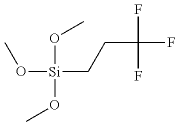 |
| B-4 | KBM-5103 | Acryl | 3-Acryloxypropyltrimethoxysilane | 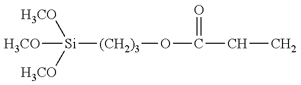 |
| B-5 | KBM-103 | Alkoxysilane | Phenyltrimethoxysilane | (CH₃O)₃SiC₆H₅ |
| B-6 | KBE-103 | | Phenyltriethoxysilane | (C₂H₅O)₃SiC₆H₅ |
| B-7 | KBM-3063 | | Hexyltrimethoxysilane | (CH₃O)₃Si(CH₂O)₅CH₃ |
| B-8 | KBE-3063 | | Hexyltriethoxysilane | (C₂H₅O)₃Si(CH₂O)₅CH₃ |
| B-9 | KBM-3103 | | Decyltrimethoxysilane | (CH₃O)₃Si(CH₂)₅CH₃ |

*All the silane coupling agents were manufactured by “Shin-Etsu Chemical Co., Ltd.”.

As is apparent from Table I, each of the laminates of Examples 1 to 6, which included the copper foil to which a silane coupling agent which had a functional group containing a N atom or a S atom was fixed, had a peel strength of 3 N/cm or more and thus had a high bonding force. The laminate of Example 1, which was subjected to the cobalt treatment, and the laminate of Example 3, which was prepared by using a silane coupling agent which had a functional group containing a N atom or a S atom and to which a phenol group was introduced, each had a particularly high bonding force.

In contrast, each of the laminates of Comparative Examples 1 to 15, in which a silane coupling agent other than a silane coupling agent which had a functional group containing a N atom or a S atom was fixed to a copper foil, had a peel strength of less than 3 N/cm and thus had a low bonding force.

A fluororesin base according to another embodiment of the present invention will now be described on the basis of Examples and Comparative Examples.

### Example 7

Table III shows test results of peeling strengths of Examples and Comparative Examples.

Samples (Samples 1 and 2) used in this test were formed as follows.

An FEP (FEP-NE-2 manufactured by Daikin Industries, Ltd.) having a thickness of 0.025 mm and dimensions of 10 mm in width×500 mm in length was used as a fluororesin sheet constituting a fluororesin layer. A glass cloth #1017 (IPC STYLE) having an average thickness of 13 μm was used as a glass cloth intermediate layer. The fluororesin layer was laminated on both surfaces of this intermediate layer. An electrolytic copper foil (thickness: 18 μm) was used as a coper foil serving as a metal base. This metal base had a surface roughness of 1.2 and a rustproofing layer containing cobalt, a silane coupling agent, etc. and having a thickness of 1 μm or less was formed on a surface of the metal base. The intermediate layer was filled with a fluororesin. According to the results of a cross-sectional observation and a measurement of the dielectric constant, it was determined that the intermediate layer had no voids.

A modified layer was formed as follows. Aminosilane was used as a silane coupling agent of a primer material. Ethanol was used as an alcohol of the primer material. Water was not added. That is, water present in air and water contained as an impurity in the alcohol were used. The concentration of the silane coupling agent was 1% by mass relative to the total mass of the primer material. A copper foil (thickness: 18 μm, surface roughness: 0.6 μm) was used as a metal base. The primer material was applied onto the copper foil serving as the metal base by an immersion method, dried, and heated at 120° C. As a result, a layer of the primer material was formed on the copper foil. Subsequently, this copper foil was thermocompression-bonded to the fluororesin sheet at 320° C.

In an etching treatment, an etchant containing iron chloride was controlled so as to have a specific gravity of 1.31 g/cm³ or more and 1.33 g/cm³ or less, and a free hydrochloride concentration of 0.1 mol/L or more and 0.2 mol/L or less, and etching was conducted at a temperature of 45° C. for an immersion time of two minutes. The modified layer formed through this treatment had a thickness of 30 nm measured with an electron microscope. After water washing and drying were conducted, a surface resistance of the resulting resin surface from which the copper foil had been removed was measured. According to the results, the surface resistance was 4.4×10¹⁵, and the volume resistance was 5.4×10¹⁵, and thus insulating properties were ensured. A fluororesin base was prepared in this manner.

Furthermore, circuits were formed at L/S=50/50, and the resulting base was then treated at 85° C. and 85% for 1,000 hours. Subsequently, migration was evaluated. According to the results, the resistance between the circuits was 10¹³ or more, which was substantially equivalent to that of initial resistance, and insulating properties were ensured.

Sample 1 was prepared as follows. After the etching treatment was performed, the fluororesin base was washed with water and dried. Immediately, the fluororesin base was covered with a polyimide sheet (hereinafter referred to as “polyimide sheet for testing”) including an epoxy resin adhesive layer having a thickness of 25 μm and a polyimide layer having a thickness of 13 μm. Subsequently, after 24 hours elapsed, a peeling strength of the polyimide sheet for testing was measured. The peeling strength was measured in accordance with JIS K 6854-2:1999 “Adhesives-Determination of peel strength of bonded assemblies, Part 2: 180 degree peel”.

Sample 2 was prepared as follows. After the etching treatment was performed, the fluororesin base was washed with water and dried. The resulting fluororesin base was left to stand in an air atmosphere for one week. The fluororesin base was then covered with the polyimide sheet for testing. Subsequently, after 24 hours elapsed, the peeling strength of the polyimide sheet for testing was measured.

On the other hand, fluororesin bases (Samples 3 and 4) for comparison were prepared by performing a plasma treatment on the fluororesin sheet (FEP (FEP-NE-2) having a thickness of 0.05 mm and dimensions of 10 mm in width×500 mm in length). Nitrogen (N₂) was used as a carrier gas. Tetrafluoromethane (CF₄) and oxygen (O₂) were used as a reaction gas. The volume ratio of the carrier gas to the reaction gas was 1,650/1,000 (carrier gas/reaction gas). The plasma treatment was performed for 30 minutes at a gas pressure of 27 Pa, a flow rate of 1,650 sccm, and an electric power of 5,000 W using a capacitively coupled plasma device.

Regarding Sample 3, immediately after the plasma treatment, the fluororesin base (plasma-treated sample) was covered with the polyimide sheet for testing. Subsequently, after 24 hours elapsed, the peeling strength of the polyimide sheet for testing was measured.

Regarding Sample 4, the fluororesin base (plasma-treated sample) was left to stand in an air atmosphere for one week. The fluororesin base was then covered with the polyimide sheet for testing. Subsequently, after 24 hours elapsed, the peeling strength of the polyimide sheet for testing was measured.

The peeling strength was measured in accordance with JIS K 6854-2: 1999 “Adhesives-Determination of peel strength of bonded assemblies, Part 2: 180 degree peel”. Table III shows the measurement results of the peeling strength.

TABLE III

| | | | Peeling strength PA | Peeling strength PB of | |
|---|---|---|---|---|---|
| | | | of adhesion product | adhesion product allowed | |
| | | | allowed to adhere | to adhere after fluororesin | |
| | | | immediately after | base/sheet was left to | Rate of |
| | Adhesion | | treatment | stand for one week | change |
| | product | Object | PA (N/cm) | PB (N/cm) | (%) |
| Sample 1 | Polyimide | Fluororesin base | 5 | | −4 |
| Sample 2 | sheet | having modified | | 4.8 | |
| | | layer | | | |
| Sample 3 | Polyimide | Fluororesin sheet + | 3 | | −93 |
| Sample 4 | sheet | plasma treatment | | 0.2 | |

### [Results]

(1) As shown in Table III, in the case where the polyimide sheet was allowed to adhere immediately after the treatment, the peeling strength of the polyimide sheet to the fluororesin base according to the present embodiment is larger than the peeling strength of the polyimide sheet to the fluororesin sheet that was subjected to the plasma treatment.

(2) In addition, regarding the fluororesin sheet that was subjected to the plasma treatment, the peeling strength of the polyimide sheet significantly decreased in the case where the fluororesin sheet was left to stand for one week. In contrast, regarding the fluororesin base according to the present embodiment, although the peeling strength slightly decreased in the case where the fluororesin base was left to stand for one week, the magnitude of the peeling strength was maintained to a certain extent. These results show that the modified layer formed on the fluororesin layer is stable.

Note that the rate of change shown in Table III is a value calculated by (PB−PA)/PA×100. In this formula, “PA” and “PB” represent the following. “PA” represents a peeling strength of a polyimide sheet for testing in the case where a modified layer was formed on a fluororesin sheet for testing, immediately after washing and drying were performed, the polyimide sheet for testing was allowed to adhere to the fluororesin sheet, and the peeling strength was measured after 24 hours elapsed. “PB” represents a peeling strength of a polyimide sheet for testing in the case where a modified layer was formed on a fluororesin sheet for testing, washing and drying were performed, the fluororesin sheet was left to stand in an air atmosphere for one week, the polyimide sheet for testing was then allowed to adhere to the fluororesin sheet, and the peeling strength was measured after 24 hours elapsed.

In this test, the peeling strengths of a polyimide sheet adhering with an epoxy resin adhesive are compared. However, regardless of the type of adhesive, the tendency of the result (2) is observed. Specifically, regarding the fluororesin sheet subjected to the plasma treatment, surface activity almost disappears after the fluororesin sheet is left to stand for one week. In contrast, the fluororesin base of the present embodiment has an adhesive property not only to an epoxy resin adhesive but also to adhesives containing a polyimide resin, a polyester resin, a polyamide resin, or the like as a main component. The adhesive property is substantially maintained even after one week. Accordingly, in the fluororesin base of the present embodiment, a decrease in surface activity is small even after the fluororesin base is left to stand for one week.

### Example 8

With regard to printed circuit boards according to the present embodiment, test results of peeling strengths are shown in Table IV. Conditions for Example will be described below.

Samples used in a reliability test were formed as follows. An FEP (NF-0050 manufactured by Daikin Industries, Ltd.) having a thickness of 0.05 mm and dimensions of 10 mm in width×500 mm in length was used as a fluororesin sheet constituting a fluororesin layer in Sample Nos. 1, 2, 5, and 6 described below. A PFA (AF-0050 manufactured by Daikin Industries, Ltd.) was used in Sample Nos. 3, 4, 7, and 8 described below.

A modified layer was formed as follows. Aminosilane was used as a silane coupling agent of a primer material. Ethanol was used as an alcohol of the primer material. Water was not added. That is, water present in air and water contained as an impurity in the alcohol were used. The concentration of the silane coupling agent was 1% by mass relative to the total mass of the primer material. A copper foil (thickness: 18 μm, surface roughness: 0.6 μm) was used as a metal base. The primer material was applied onto the copper foil serving as the metal base by an immersion method, dried, and heated at 120° C. As a result, a layer of the primer material was formed on the copper foil. The primer layer had a thickness of 30 nm. Subsequently, this copper foil was thermocompression-bonded to the fluororesin sheet.

Next, 25 copper wirings were formed by an etching method at a pitch of 100 μm so as to have a thickness of 18 μm and a width of 100 μm. In an etching treatment, an etchant containing iron chloride was controlled so as to have a specific gravity of 1.31 g/cm³ or more and 1.33 g/cm³ or less, and a free hydrochloride concentration of 0.1 mol/L or more and 0.2 mol/L or less, and etching was conducted at a temperature of 45° C. for an immersion time of two minutes.

The copper wirings were covered with a polyimide sheet including an epoxy resin adhesive layer having a thickness of 25 μm and a polyimide layer having a thickness of 13 μm. In the reliability test, the resulting printed circuit boards were left to stand for 100 hours at a relative humidity of 85% and a temperature of 85° C. The peeling strengths of the copper wiring and the polyimide sheet were measured.

The peeling strengths were measured before and after the reliability test. Regarding products relating to the measurement of the peeling strengths, products adjacent to each other were used before and after the reliability test. The peeling strengths were measured in accordance with JIS K 6854-2:1999 “Adhesives-Determination of peel strength of bonded assemblies, Part 2: 180 degree peel”.

TABLE IV

| | | Peeling | Peeling | |
|---|---|---|---|---|
| | | strength P1 | strength P2 | |
| | | before | after | Rate of |
| | Adhesion | reliability test | reliability test | change |
| | product | (N/cm) | (N/cm) | (%) |
| No 1 | Copper wiring | 3.0 | 3.0 | 0 |
| No 2 | Copper wiring | 7.0 | 7.0 | 0 |
| No 3 | Copper wiring | 1.0 | 1.0 | 0 |
| No 4 | Copper wiring | 9.0 | 8.7 | −3 |
| No 5 | Polyimide sheet | 9.0 | 9.0 | 0 |
| No 6 | Polyimide sheet | 1.0 | 1.0 | 0 |
| No 7 | Polyimide sheet | 6.5 | 6.2 | −5 |
| No 8 | Polyimide sheet | 2.5 | 2.4 | −4 |

[Results]

(1) As shown in Table IV, regarding Sample Nos. 1 to 8, the peeling strength before the reliability test is 1.0 N/cm or more, which satisfies a criterion.

(2) Regarding Sample Nos. 1 to 8, the rate of change in the peeling strength between before and after the reliability test is small. Specifically, the rate of change in the peeling strength ((P2−P1)/P1×100) is within the range of ±10%, which satisfies a criterion. Thus, in the printed circuit boards of the present embodiment, the peeling strengths of the conductive wiring 11 and the polyimide sheet (covering member) are high, and the rate of change in the peeling strength before and after the reliability test is small.

(3) Furthermore, the following test was conducted, though Tables III and IV do not show the results. A test of etching resistance was conducted using samples (Nos. 11 to 18) prepared under the same conditions as those of Sample Nos. 1 to 8 of Example 8. Note that a copper foil of each of the samples was completely removed by etching, and no copper wiring was formed. Specifically, only a modified layer was formed on a surface of each of the fluororesin bases. In order to confirm etching resistance of the fluororesin base (including the modified layer), the fluororesin base was immersed for two minutes in an etchant that was controlled so as to have a temperature of 45° C., a specific gravity of 1.31 g/cm³ or more and 1.33 g/cm³ or less, and a free hydrochloride concentration of 0.1 mol/L or more and 0.2 mol/L or less. The peeling strengths of a polyimide sheet for testing were compared before and after this etching test. According to the results, regarding any of the samples, the rate of change in the peeling strength was within ±10%. Herein, the rate of change is a value represented by a formula of (peeling strength after etching test−peeling strength before etching test)/(peeling strength before etching test)×100. That is, according to these results, it is found that, considering that an etching rate decreases with a decrease in the temperature, the modified layer has etching resistance to at least an etching treatment including immersion using an etchant having a specific gravity of 1.31 g/cm³ or more and 1.33 g/cm³ or less, and a free hydrochloride concentration of 0.1 mol/L or more and 0.2 mol/L or less at 45° C. or lower for two minutes or less.

This means the following. Regarding a fluororesin base with a copper foil (fluororesin base including a copper foil, a fluororesin layer, and a modified layer interposed between the copper foil and the fluororesin layer), in an etching treatment including immersion using the above etchant at 45° C. or lower for two minutes or less, the time during which the exposed modified layer is exposed to the etchant is two minutes or less. Therefore, it is believed that when the fluororesin base is etched under such etching conditions, degradation of the modified layer is further suppressed.

(4) Furthermore, a test of the contact angle with water (hereinafter referred to as “angle of contact with water”) was conducted using samples (Nos. 21 to 28) prepared under the same conditions as those of Sample Nos. 1 to 8, though Tables III and IV do not show the results. The test results will be described below.

The contact angle with water (hereinafter referred to as “angle of contact with water”) of the PFA before the modified layer formation process was 115° on average, and the angle of contact with water of the FEP before the modified layer formation process was 114° on average. In contrast, regarding the PFA (or FEP) prepared by bonding a copper foil to the PFA (or FEP) with a silane coupling agent therebetween, and then removing the copper foil by etching, the angle of contact with water decreased to 60° to 80°. Accordingly, it was confirmed that hydrophilization is caused by the modified layer formation process (process including bonding a copper foil to a fluororesin with a primer material therebetween, and then removing the copper foil). Therefore, according to the modified layer formation process, the adhesive strength of an epoxy adhesive or the like to a surface subjected to the etching removal can be made higher than that to a fluororesin that is not subjected to the process.

### [Supplementary Notes]

The above embodiment discloses technical ideas described below.

(Supplementary note 1) A fluororesin base including a fluororesin layer and a modified layer formed on at least a part of a surface of the fluororesin layer,

in which the modified layer has a siloxane-bond structure, contains a functional group other than a siloxane group, and has hydrophilicity represented by a contact angle with pure water of 90° or less.

(Supplementary note 2) The fluororesin base according to supplementary note 1, in which, in the part where the modified layer is formed, a peeling strength of a polyimide sheet bonded with an epoxy resin adhesive is 1.0 N/cm or more.
(Supplementary note 3) The fluororesin base according to supplementary note 1 or 2, in which the modified layer has etching resistance to an etching treatment including immersion using an etchant containing iron chloride, having a specific gravity of 1.31 g/cm³ or more and 1.33 g/cm³ or less, and a free hydrochloride concentration of 0.1 mol/L or more and 0.2 mol/L or less at 45° C. or lower for two minutes or less.
(Supplementary note 4) The fluororesin base according to any one of supplementary notes 1 to 3, in which the fluororesin base has a region where a mean surface roughness Ra of the modified layer is 4 μm or less.

According to the present embodiment, the following advantages are achieved.

(1) A fluororesin base according to the present embodiment includes a fluororesin layer and a modified layer formed on at least a part of a surface of the fluororesin layer. The modified layer has a siloxane-bond structure, contains a functional group other than a siloxane group, and has hydrophilicity represented by a contact angle with pure water of 90° or less.

Since the modified layer has hydrophilicity represented by a contact angle with pure water of 90° or less, the fluororesin base is rich in reactivity. Herein, the term “rich in reactivity” covers a case where a physical action such as an adhesive property is large. Therefore, the fluororesin base is surface-active. In addition, since the modified layer has a siloxane-bond structure, the modified layer is stable with time. Specifically, in the fluororesin base having the above structure, a surface-modified state (surface-active state) is more stable than those of existing fluororesin bases.

(2) In the part where the modified layer of the fluororesin base is formed, a peeling strength of a polyimide sheet bonded with an epoxy resin adhesive is preferably 1.0 N/cm or more. With this structure, the polyimide sheet is not easily detached from the fluororesin base. More preferably, the peeling strength is 5.0 N/cm or more.

(3) The modified layer of the fluororesin base preferably has the following structure. Specifically, the modified layer preferably has etching resistance to an etching treatment including immersion using an etchant containing iron chloride, having a specific gravity of 1.31 g/cm³ or more and 1.33 g/cm³ or less, and a free hydrochloride concentration of 0.1 mol/L or more and 0.2 mol/L or less at 45° C. or lower for two minutes or less.

With this structure, even when a metal layer is formed on the fluororesin base and an etching treatment is performed, the surface-modified state (surface activity) of the fluororesin base can be maintained. Therefore, in the case where various treatments are performed on the fluororesin base after the etching treatment, the state after the treatments can be made satisfactory. For example, a treatment of applying a solder resist to a fluororesin base, and a treatment of applying an adhesive to a fluororesin base are often performed after etching. However, even when an etching treatment is performed on the fluororesin base, the modified layer is maintained. Accordingly, the peeling strengths of these adhesion products (solder resist and adhesive) become sufficiently high values.

(4) The fluororesin base may have a region where a mean surface roughness Ra of the modified layer is 4 μm or less. With this structure, when a fluororesin base is used as a circuit board, good high-frequency characteristics can be obtained. For example, by specifying the mean surface roughness Ra of the modified layer to 4 μm or less, signal transmission loss of a high-frequency signal in a conductive wiring on the modified layer can be reduced as compared with the case where the mean surface roughness Ra is specified to more than 4 μm.

(5) In the fluororesin base, the modified layer preferably has a thickness of 400 nm or less on average. With this structure, it is possible to suppress a decrease in high-frequency characteristics due to the thickness of the modified layer when the fluororesin base is used as a wiring board, compared with the case where the thickness of the modified layer is more than 400 nm on average.

(6) In the fluororesin base, a bond between the modified layer and the fluororesin layer is preferably a chemical bond. Specifically, the bond is not a bond formed by a physical action due to a simple anchoring effect but is preferably any of a covalent bond and a bond including both a hydrogen bond and a covalent bond. With this structure, the bond between the modified layer and the fluororesin is increased compared with the case where the modified layer and the fluororesin layer are simply bonded by a physical action. Therefore, the surface modified state of the fluororesin base can be maintained for a long period of time compared with a fluororesin base in which a modified layer is simply bonded to a fluororesin only by a physical action such as an anchoring effect.

### INDUSTRIAL APPLICABILITY

According to the present invention, a metal-resin composite body having good high-frequency signal transmission characteristics and good adhesiveness between a synthetic resin portion and a base portion is provided. Accordingly, the metal-resin composite body of the present invention can be suitably used in a tape electrical wire or an FPC. According to the present invention, a method for producing a metal-resin composite body having good high-frequency signal transmission characteristics and good adhesiveness is further provided.

### REFERENCE SIGNS LIST

1, 1A, 1B metal-resin composite body
2 synthetic resin portion
20 one surface (of synthetic resin portion)
3, 3B base portion
30, 31 one surface (of base portion)
4A reinforcing layer
5A cushioning material
6 tape electrical wire
60 synthetic resin portion
61 base portion
7 flexible printed circuit board
70 synthetic resin portion
71 base portion
72 cover film
73 adhesive layer
101 . . . fluororesin base
102 . . . fluororesin layer
103 . . . modified layer

1. A metal-resin composite body comprising a base portion composed of a metal; and a synthetic resin portion that is bonded to at least a part of an outer surface of the base portion and that contains a fluororesin as a main component,
wherein a silane coupling agent which has a functional group containing a N atom or a S atom is present in the vicinity of an interface between the base portion and the synthetic resin portion.

2. The metal-resin composite body according to claim 1, wherein the silane coupling agent is an aminoalkoxysilane, an ureidoalkoxysilane, a mercaptoalkoxysilane, a sulfide alkoxysilane, or a derivative thereof.

3. The metal-resin composite body according to claim 2, wherein the silane coupling agent is an aminoalkoxysilane to which a modifying group is introduced.

4. The metal-resin composite body according to claim 3, wherein the modifying group is a phenyl group.

5. The metal-resin composite body according to claim 1, wherein the fluororesin is a tetrafluoroethylene/hexafluoropropylene copolymer (FEP), a tetrafluoroethylene/perfluoroalkyl vinyl ether copolymer (PFA), polytetrafluoroethylene (PTFE), or a tetrafluoroethylene/perfluorodioxole copolymer (TFE/PDD).

6. The metal-resin composite body according to claim 1, wherein the base portion includes a rustproofing layer on a surface bonded to the synthetic resin portion side.

7. The metal-resin composite body according to claim 6, wherein the rustproofing layer contains a cobalt oxide.

8. The metal-resin composite body according to claim 1, wherein a peeling strength between the base portion and the synthetic resin portion is 3 N/cm or more.

9. The metal-resin composite body according to claim 1, wherein the base portion and the synthetic resin portion each have a thickness of 5 to 50 μm.

10. A wiring material comprising the metal-resin composite according to claim 1.

11. A method for producing a metal-resin composite body, the method comprising the steps of:
applying a composition containing a silane coupling agent which has a functional group containing a N atom or a S atom onto at least a part of an outer surface of a base portion composed of a metal;
drying the composition; and
bonding a synthetic resin portion containing a fluororesin as a main component to at least a composition-applied surface in the outer surface of the base portion.
